(19) United States
(12) Patent Application Publication
(10) Pub. No.: US 2019/0206691 A1
(43) Pub. Date: Jul. 4, 2019

(54) HIGH-K GATE INSULATOR FOR A THIN-FILM TRANSISTOR

(71) Applicant: Applied Materials, Inc., Santa Clara, CA (US)

(72) Inventors: Yujia ZHAI, Fremont, CA (US); Xiangxin RUI, Campbell, CA (US); Lai ZHAO, Campbell, CA (US); Dong-Kil YIM, Pleasanton, CA (US); Soo Young CHOI, Fremont, CA (US)

(21) Appl. No.: 15/862,522

(22) Filed: Jan. 4, 2018

(51) Int. Cl. H01L 21/28; H01L 21/02; H01L 29/423; H01L 49/02; H01L 29/51; H01L 29/78

(52) U.S. Cl. CPC H01L 21/28167; H01L 21/02148; H01L 29/42364; H01L 21/3105; H01L 29/513; H01L 29/78; H01L 29/517; H01L 28/56

(57) ABSTRACT

Embodiments of the present disclosure generally relate to a layer stack including a dielectric layer having a high K value capable of improving semiconductor display device electrical performance. In one embodiment, the layer stack includes a substrate, a channel layer disposed on the substrate, and a gate insulating layer. The gate insulating layer includes an interface layer disposed on the channel layer and a zirconium dioxide layer disposed on the interface layer. The gate insulating layer has a K value ranging from about 20 to about 50. The high k value of the gate insulating layer reduces the subthreshold swing (SS) causing a higher energy barrier which alleviates the short channel effect and leakage in display devices. Additionally, the high k value of the gate insulating layer enables for a faster driving current that improves brightness and performance of the display device.

### BACKGROUND

### Field

Embodiments of the present disclosure generally relate to a layer stack including a dielectric layer having a high dielectric constant (high K) value for display devices.

### Description of the Related Art

Display devices have been widely used for a wide range of electronic applications, such as TVs, monitors, mobile phone, MP3 players, e-book readers, personal digital assistants (PDAs) and the like. Those display devices are manufactured using integrated circuits that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials as well as high dielectric constant insulating materials to obtain suitable electrical performance from such components.

The demands of reducing the scale of these components lead to leakage and short channel effect (DIBL) problems. In order to overcome leakage and DIBL problems, thin film transistors (TFTs) as formed are required to have high capacitance for display devices. The capacitance may be adjusted by changing the dielectric material and/or the dimensions of the dielectric layer. For example, when the dielectric layer is replaced with a material having a higher K value, the capacitance of the TFT will increase as well, as noted in the formula Cₒₓ=A (k·E₀/tₒₓ). However, changing the material to a material having a high K value may cause interface problems between the channel region and the dielectric layer disabling the device altogether.

Therefore, there is a need for a dielectric layer with a high k value capable of improving semiconductor display device electrical performance.

### SUMMARY

Embodiments of the present disclosure generally relate to a layer stack including a dielectric layer having a high K value capable of improving semiconductor display device electrical performance. In one embodiment, the layer stack includes a substrate, a channel layer disposed on the substrate, and a gate insulating layer. The gate insulating layer includes an interface layer disposed on the channel layer and a zirconium dioxide layer disposed on the interface layer. The gate insulating layer has a K value ranging from about 20 to about 50.

In another embodiment, a layer stack includes a substrate, a channel layer disposed on the substrate, and a gate insulating layer disposed on the channel layer. The gate insulating layer includes a first interface layer, a second interface layer, and a zirconium dioxide layer between the first interface layer and the second interface layer. The gate insulating layer has a K value ranging from about 20 to about 50.

In another embodiment, a layer stack includes an amorphous silicon layer and a gate insulating layer disposed on the amorphous silicon layer. The gate insulating layer includes a silicon dioxide layer disposed on the amorphous silicon layer and a zirconium dioxide layer disposed on the silicon dioxide layer. The gate insulating layer has a K value ranging from about 20 to about 50.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross-sectional view of a processing chamber that may be used to deposit a gate insulating layer in accordance with one embodiment of the present disclosure.

FIG. 2 is a cross-sectional view of a layer stack in accordance with one embodiment of the present disclosure.

FIG. 3 is a cross-sectional view of a layer stack in accordance with one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a layer stack including a gate insulating layer having a high K value capable of improving semiconductor display device electrical performance The high K insulating layer has a K value of 20 or higher and may be formed as a part of a thin film transistor, a gate insulating layer, or any suitable insulating layer in display devices. The layer stack includes a substrate, a channel layer disposed on the substrate, and a gate insulating layer. The gate insulating layer includes an interface layer disposed on the channel layer and a gate insulating layer disposed on the interface layer. The gate insulating layer has a K value ranging from about 20 to about 50. The high k value of the gate insulating layer reduces the subthreshold swing (SS) causing a higher energy barrier which alleviates the short channel effect and leakage in display devices. Additionally, the high k value of the gate insulating layer enables for a faster driving current that improves brightness and performance of the display device.

The terms “over,” “under,” “between,” and “on” as used herein refer to a relative position of one layer with respect to other layers. As such, for example, one layer disposed over or under another layer may be directly in contact with the other layer or may have one or more intervening layers. Moreover, one layer disposed between layers may be directly in contact with the two layers or may have one or more intervening layers. In contrast, a first layer “on” a second layer is in contact with the second layer. Additionally, the relative position of one layer with respect to other layers is provided assuming operations are performed relative to a substrate without consideration of the absolute orientation of the substrate.

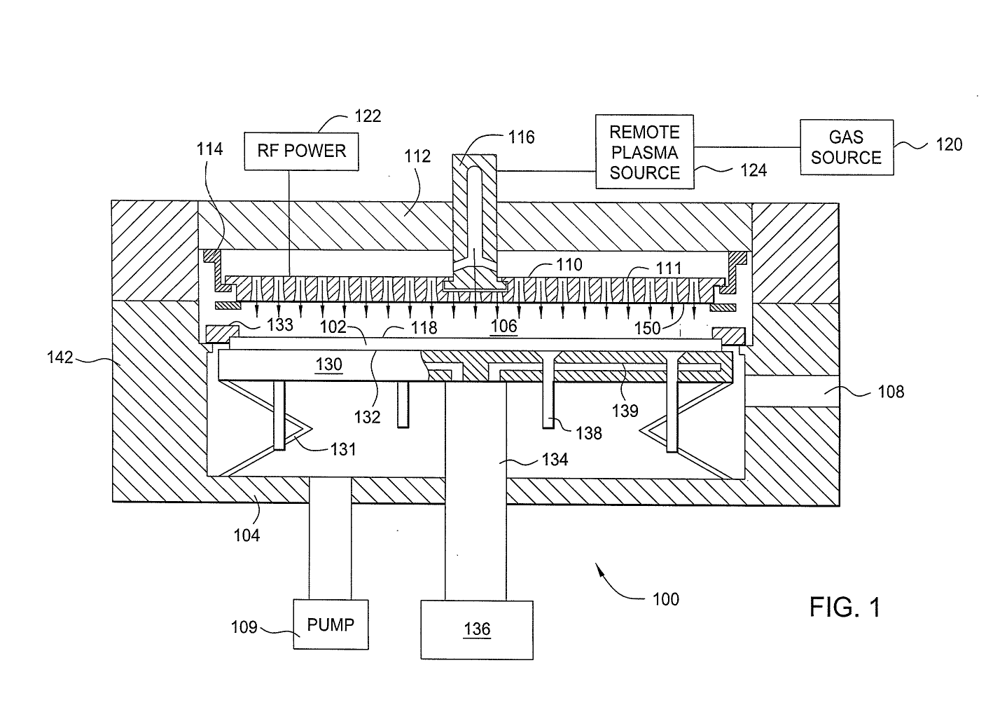

FIG. 1 is a schematic cross-section view of one embodiment of a chemical vapor deposition (CVD) processing chamber 100 in which a high K dielectric layer, such as a ZrO₂ layer for display device structures, may be deposited. One suitable CVD processing chamber, such as plasma enhanced CVD (PECVD) processing chamber, is available from Applied Materials, Inc., located in Santa Clara, Calif. It is contemplated that other deposition chambers, including those from other manufacturers, may be utilized to practice the present disclosure.

The chamber 100 generally includes one or more walls 142, a bottom 104 and a lid 112 which bound a process volume 106. A gas distribution plate 110 and substrate support assembly 130 are disposed within the process volume 106. The process volume 106 is accessed through a slit valve opening 108 formed through the wall 142 such that a substrate 102 may be transferred into and out of the chamber 100.

The substrate support assembly 130 includes a substrate receiving surface 132 for supporting the substrate 102. A stem 134 couples the substrate support assembly 130 to a lift system 136 which raises and lowers the substrate support assembly 130 between substrate transfer and processing positions. A shadow frame 133 may be optionally placed over periphery of the substrate 102 during processing to prevent deposition on the edge of the substrate 102. Lift pins 138 are moveably disposed through the substrate support assembly 130 and are adapted to space the substrate 102 from the substrate receiving surface 132. The substrate support assembly 130 may also include heating and/or cooling elements 139 utilized to maintain the substrate support assembly 130 at a predetermined temperature. The substrate support assembly 130 may also include grounding straps 131 to provide an RF return path around the periphery of the substrate support assembly 130.

The gas distribution plate 110 is coupled at its periphery to the lid 112 or wall 142 of the chamber 100 by a suspension 114. The gas distribution plate 110 is also coupled to the lid 112 by one or more center supports 116 to help prevent sag and/or to control the straightness/curvature of the gas distribution plate 110. It is contemplated that the one or more center supports 116 may not be utilized. The gas distribution plate 110 may have different configurations with different dimensions. The gas distribution plate 110 has a downstream surface 150 having a plurality of apertures 111 formed therein facing an upper surface 118 of the substrate 102 disposed on the substrate support assembly 130. The apertures 111 may have different shapes, number, densities, dimensions, and distributions across the gas distribution plate 110. In one embodiment, a diameter of the apertures 111 may be selected between about 0.01 inch and about 1 inch.

A gas source 120 is coupled to the lid 112 to provide gas through the lid 112 and then through the apertures 111 formed in the gas distribution plate 110 to the process volume 106. A vacuum pump 109 is coupled to the chamber 100 to maintain the gas in the process volume 106 at a predetermined pressure.

An RF power source 122 is coupled to the lid 112 and/or to the gas distribution plate 110 to provide a RF power that creates an electric field between the gas distribution plate 110 and the substrate support assembly 130 so that a plasma may be generated from the gases present between the gas distribution plate 110 and the substrate support assembly 130. The RF power may be applied at various RF frequencies. For example, RF power may be applied at a frequency between about 0.3 MHz and about 200 MHz. In one embodiment the RF power is provided at a frequency of 13.56 MHz.

A remote plasma source 124, such as an inductively coupled remote plasma source, is coupled between the gas source 120 and the gas distribution plate 110. Between processing substrates, a cleaning gas may be energized in the remote plasma source 124 to remotely provide plasma utilized to clean chamber components. The cleaning gas entering the process volume 106 may be further excited by the RF power provided to the gas distribution plate 110 by the power source 122. Suitable cleaning gases include, but are not limited to, NF₃, F₂, and SF₆.

In one embodiment, the substrate 102 that may be processed in the chamber 100 may have a surface area of 10,000 cm² or more, such as 25,000 cm² or more, for example about 55,000 cm² or more. It is understood that after processing the substrate may be cut to form smaller other devices. In one embodiment, the heating and/or cooling elements 139 may be set to provide a substrate support assembly temperature during deposition of about 600 degrees Celsius or less, for example between about 100 degrees Celsius and about 500 degrees Celsius, or between about 200 degrees Celsius and about 500 degrees Celsius, such as about 300 degrees Celsius and 500 degrees Celsius.

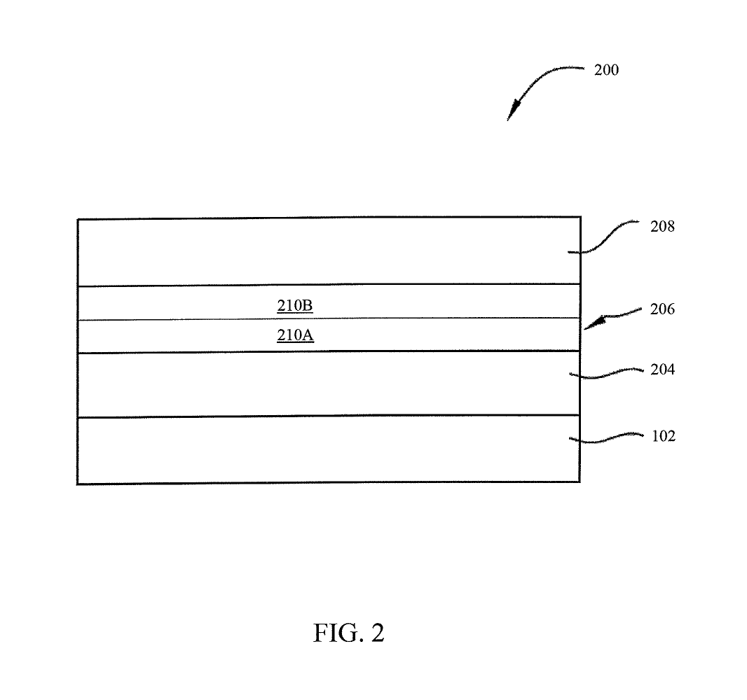

FIG. 2 is a cross-sectional view of a layer stack 200 in accordance with one embodiment of the present disclosure. The layer stack 200 includes the substrate 102, a channel layer 204, a gate insulating layer 206, and a metal layer 208. The substrate 102 may be fabricated from a silicate glass. The channel layer 204 may be fabricated from amorphous silicon, low-temperature polycrystalline silicon (LTPS), or other metal oxide semiconductor material. The metal layer 208 may be fabricated from aluminum, titanium, copper or any other suitable metal. In the embodiment of FIG. 2, the channel layer 204 is between the substrate 102 and the gate insulating layer 206 in a top gate structure. The gate insulating layer 206 is between the metal layer 208 and the channel layer 204. It can be imagined that the embodiments described herein can be utilized in a bottom gate structure as well.

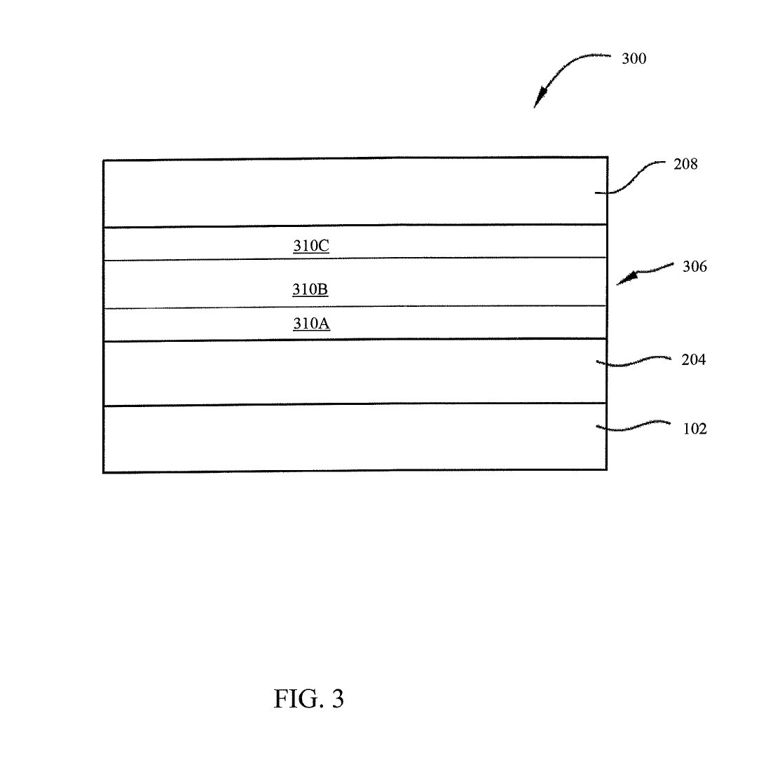

In the implementation of FIG. 2, the gate insulating layer 206 has two layers. In the embodiment of FIG. 3 (described in more detail below), the gate insulating layer 306 has three layers 310A, 310B, 310C. While, the gate insulating layer is shown as having two layers, more layers are possible. For example, the gate insulating layer may have multiple alternating layers of the interface layer 210A and the high k dielectric layer 210B. In one embodiment, the gate insulating layer has more than 2 layers. In another embodiment, the gate insulating layer has more than three layers.

In the embodiment of FIG. 2, the gate insulating layer 206 has an interface layer 210A and a high k dielectric layer 210B. The interface layer 210A is distinct from the high K dielectric layer 210B. In one embodiment, the interface layer 210A has a K value ranging from about 3 to about 5. The interface layer 210A may be fabricated from any suitable interface material, such as an oxide, for example silicon dioxide (SiO₂), aluminum oxide (Al₂O₃), or titanium dioxide (TiO₂). The interface layer 210A has a thickness ranging from about 2 Angstroms to about 100 Angstroms. In one embodiment, the interface layer 210A is deposited in a CVD chamber, such as a PECVD chamber, for example the chamber 100 shown in FIG. 1.

In one embodiment, the high K dielectric layer 210B formed on the interface layer 210A has a k value that ranges from about 20 to about 50. The high k dielectric layer 210B is a material selected from the group consisting of zirconium dioxide (ZrO₂), hafnium dioxide (Hf₂O₂), titanium dioxide (TiO₂), and aluminum oxide (Al₂O₃). The high k dielectric layer 210B has a thickness ranging from about 100 Angstroms to about 900 Angstroms. In one embodiment, the high k dielectric layer 2106 has a thickness ranging from about 250 Angstroms to about 600 Angstroms. In one embodiment, the interface layer 210A has a thickness of 100 A and the high k dielectric layer 210B has a thickness of 600 A. In some embodiments, the high k dielectric layer 210B may be deposited on the substrate 102 in a PECVD chamber, such as the chamber 100 shown in FIG. 1. In one embodiment, the interface layer 210A and the high K dielectric layer 210B are deposited in the same process chamber.

If a high K dielectric layer, such as the high k dielectric layer 210B, is deposited directly on the channel layer 204, there is an interface mismatch that compromises the integrity of the display device. As such, in order to form a high K dielectric layer within the display device having a uniform thickness profile, the interface layer 210A is between the high k dielectric layer 2106 and the channel layer 204. The interface layer 210A advantageously has a good interface between both the channel layer 204 and the high k dielectric layer 210B thereby improving adhesion. The high k dielectric layer 210B advantageously has a high k value. The high k value layer can reduce the subthreshold swing (SS) causing a higher energy barrier which alleviates the short channel effect and leakage in display devices. Additionally, the high k value layer enables for a faster driving current that improves brightness and performance of the display device.

FIG. 3 is a cross-sectional view of a layer stack 300 in accordance with one embodiment of the present disclosure. The layer stack 300 includes the substrate 102, a channel layer 204, a gate insulating layer 306, and a metal layer 208. In one embodiment, the channel layer 204 is between the substrate 102 and the gate insulating layer 306. The gate insulating layer 306 is between the metal layer 208 and the channel layer 204.

In the embodiment of FIG. 3, the gate insulating layer 306 has a first interface layer 310A, a high k dielectric layer 310B, and a second interface layer 310C. The interface layers 310A, 310C are distinct from the high K dielectric layer 310B. In one embodiment, first interface layer 310A has a K value ranging from about 3 to about 5. The first interface layer 310A may be fabricated from any suitable interface material, such as an oxide, for example SiO₂, aluminum oxide (Al₂O₃), or titanium dioxide (TiO₂). The first interface layer 310A has a thickness ranging from about 2 Angstroms to about 100 Angstroms. In one embodiment, first interface layer 310A is deposited in a CVD chamber, such as a PECVD chamber, for example the chamber 100 shown in FIG. 1.

In one embodiment, the second interface layer 310C is the same material as the first interface layer 310A. In another embodiment, the second interface layer 310C is a different material than the first interface layer 310A. In one embodiment, second interface layer 310C has a K value ranging from about 3 to about 5. The second interface layer 310C may be fabricated from any suitable interface material, such as an oxide, for example SiO₂, aluminum oxide (Al₂O₃), or titanium dioxide (TiO₂). The second interface layer 310C has a thickness ranging from about 2 Angstroms to about 100 Angstroms. In one embodiment, second interface layer 310C is deposited in a CVD chamber, such as a PECVD chamber, for example the chamber 100 shown in FIG. 1.

In one embodiment, the high K dielectric layer 310B is formed between the first interface layer 310A and the second interface layer 310C. In one embodiment, the first interface layer 310A is adjacent the channel layer 204. In another embodiment, the second interface layer 310C is adjacent the channel layer 204. The high k dielectric layer 310B has a k value that ranges from about 20 to about 50. In another embodiment, the high K dielectric layer 310B formed on the second interface layer 310C. The high k dielectric layer 310B is a material selected from the group consisting of zirconium dioxide (ZrO₂), hafnium dioxide (Hf₂O₂), titanium dioxide (TiO₂), and aluminum oxide (Al₂O₃). The high k dielectric layer 310B has a thickness ranging from about 100 Angstroms to about 900 Angstroms. In one embodiment, the high k dielectric layer 310B has a thickness ranging from about 250 Angstroms to about 600 Angstroms. In one embodiment, the first interface layer 310A has a thickness of 100 A, the high k dielectric layer 310B has a thickness of 600 A, and the second interface layer 310C has a thickness of 100 A. In some embodiments, the high k dielectric layer 310B may be deposited on the substrate 102 in a PECVD chamber, such as the chamber 100 shown in FIG. 1. In one embodiment, the first interface layer 310A, the second interface layer 310C, and the high K dielectric layer 310B are deposited in the same process chamber.

By including zirconium oxide into the multilayer gate insulating layer, a higher K dielectric layer is realized. The silicon containing interface layer improves adhesion and interaction between the active channel layer and the metal gate. The zirconium oxide dielectric layer increases the k value of the gate insulating layer. The high k value of the gate insulating layer reduces the subthreshold swing (SS) causing a higher energy barrier which alleviates the short channel effect and leakage in display devices. Additionally, the high k value of the gate insulating layer enables for a faster driving current that improves brightness and performance of the display device.

While the foregoing is directed to embodiments of the present disclosure, other and further embodiments of the disclosure may be devised without departing from the basic scope thereof, and the scope thereof is determined by the claims that follow.

1.-15. (canceled)

16. A layer stack, comprising:
an amorphous silicon layer; and
a gate insulating layer disposed on the amorphous silicon layer, wherein the gate insulating layer comprises:
a silicon dioxide layer disposed on the amorphous silicon layer; and
a zirconium dioxide layer disposed on the silicon dioxide layer,
wherein the gate insulating layer has a K value ranging from about 20 to about 50.

17. The layer stack of claim 16, further comprising a metal gate layer.

18. The layer stack of claim 17, wherein the metal gate layer is disposed on top of the zirconium dioxide layer.

19. The layer stack of claim 16, wherein the zirconium dioxide layer has a thickness ranging from about 250 Angstroms to about 900 Angstroms.

20. The layer stack of claim 16, wherein the silicon dioxide layer has a thickness ranging from about 2 Angstroms to about 100 Angstroms.

21. The layer stack of claim 20, wherein the silicon dioxide layer has a K value ranging from about 3 to about 5.

22. The layer stack of claim 19, wherein the zirconium dioxide layer has a K value ranging from about 20 to about 50.
